(19) United States
(12) Patent Application Publication
(10) Pub. No.: US 2025/0096731 A1
(43) Pub. Date: Mar. 20, 2025

(54) AVERAGE POWER TRACKING MODULE, AVERAGE POWER TRACKING CIRCUIT, COMMUNICATION DEVICE, AND METHOD FOR SUPPLYING POWER SUPPLY VOLTAGE

(71) Applicant: Murata Manufacturing Co., Ltd., Nagaokakyo-shi (JP)

(72) Inventors: Kenzou OOMORI, Nagaokakyo-shi (JP); Takeshi KOGURE, Nagaokakyo-shi (JP); Yuuki FUKUDA, Nagaokakyo-shi (JP); Toshiki MATSUI, Nagaokakyo-shi (JP)

(21) Appl. No.: 18/963,859

(22) Filed: Nov. 29, 2024

Related U.S. Application Data
(63) Continuation of application No. PCT/JP2023/007830, filed on Mar. 2, 2023.

(30) Foreign Application Priority Data
Jun. 1, 2022 (JP) 2022-089921

(51) Int. Cl. H03F 1/02; H03F 3/24

(52) U.S. Cl. CPC H03F 1/0233; H03F 3/245; H03F 2200/102; H03F 2200/451

(57) ABSTRACT

An APT module is provided that includes a converter circuit that outputs a power supply voltage, output terminals to which the power supply voltage is applied, a FB terminal connected to a signal path connecting the output terminal and power amplifiers, a FB terminal connected to a signal path connecting the output terminal and power amplifiers, and a control circuit connected to the FB terminals and the converter circuit.

### CROSS REFERENCE TO RELATED APPLICATIONS

This application is a continuation of International Application No. PCT/JP2023/007830, filed Mar. 2, 2023, which claims priority to Japanese Patent Application No. 2022-089921, filed Jun. 1, 2022, the entire contents of each of which are hereby incorporated by reference in their entireties.

### TECHNICAL FIELD

The exemplary aspects of the present disclosure relate to an average power tracking module, an average power tracking circuit, a communication device, and a method for supplying a power supply voltage.

### BACKGROUND

U.S. Pat. No. 9,041,464 discloses an average power tracking (APT) scheme for controlling a power supply voltage from a power amplifying module based on average output power. This scheme enables power efficiency to be improved.

However, in simultaneously sending radio frequency signals in a plurality of bands simultaneously by using the APT scheme disclosed in U.S. Pat. No. 9,041,464, a plurality of power supply voltages are simultaneously supplied to a plurality of power amplifiers from the APT module that supplies a power supply voltage, and thus the APT module is upsized on occasions.

### SUMMARY OF THE INVENTION

In view of the foregoing, the exemplary aspects of the present disclosure provide a small average power tracking module, an average power tracking circuit, and a communication device that supply a power supply voltage to a power amplifier in simultaneously sending a plurality of radio frequency signals and a method for supplying a power supply voltage for enabling the plurality of radio frequency signals to be sent simultaneously.

In an exemplary aspect, an average power tracking module is provided that includes a first output terminal and a second output terminal; a converter circuit configured to output a first voltage to the first output terminal and the second output terminal; a first feedback terminal connected to a path between a first power amplifier and the first output terminal; a second feedback terminal connected to a path between a second power amplifier and the second output terminal; and a control circuit connected to the first feedback terminal, the second feedback terminal, and the converter circuit.

In another exemplary aspect, a communication device is provided that includes a signal processing circuit configured to process a radio frequency signal; the above-described average power tracking module configured to transmit the radio frequency signal between the signal processing circuit and an antenna; a first amplifying module that is connected between the average power tracking module and the antenna and that includes the first power amplifier; a second amplifying module that is connected between the average power tracking module and the antenna and that includes the second power amplifier; and a mother board on which the signal processing circuit, the average power tracking module, the first amplifying module, and the second amplifying module are disposed. In a plan view of a main surface of the mother board, the average power tracking module is disposed between the first amplifying module and the second amplifying module.

In an exemplary aspect, an average power tracking circuit is provided that includes a converter circuit configured to output a first voltage; a first switch disposed on a first path that connects the converter circuit and a first power amplifier and that is configured to supply the first voltage to the first power amplifier; and a second switch disposed on a second path that connects the converter circuit and a second power amplifier and that is configured to supply the first voltage to the second power amplifier. The first switch and the second switch are configured to conduct simultaneously.

In yet another exemplary aspect, a method is provided for supplying a power supply voltage to a first power amplifier and a second power amplifier configured to simultaneously send respective radio frequency signals. The method includes selecting, as a first voltage, a higher voltage of a first power supply voltage based on output power of the first power amplifier and a second power supply voltage based on output power of the second power amplifier; and supplying the selected first voltage to both of the first power amplifier and the second power amplifier.

According to the exemplary aspects of the present disclosure, any one of the small average power tracking module, the average power tracking circuit, and the communication device that supply a power supply voltage to the power amplifier in simultaneously sending the plurality of radio frequency signals or the method for supplying a power supply voltage for enabling the plurality of radio frequency signals to be sent simultaneously is provided.

### BRIEF DESCRIPTION OF DRAWINGS

FIG. 1A is a graph illustrating an example of power supply voltage changes in an average power tracking mode.

FIG. 1B is a graph illustrating an example of power supply voltage changes in an analog envelope tracking mode.

FIG. 1C is a graph illustrating an example of power supply voltage changes in a digital envelope tracking mode.

FIG. 2A is a view of the circuit configuration of an APT module and a communication device according to an exemplary embodiment.

FIG. 2B is a view of the circuit configuration of an APT module and a communication device according to Modification 1.

FIG. 3A is a flowchart illustrating a first example of a method for supplying a power supply voltage according to the exemplary embodiment.

FIG. 3B is a flowchart illustrating a second example of the power supply voltage supply method according to the exemplary embodiment.

FIG. 4 is a view illustrating an example of the lookup table of the APT module according to the exemplary embodiment.

FIG. 5 is a view of the circuit configuration of an APT module and a communication device according to Modification 2.

FIG. 6 is a view of the circuit configuration of an APT module and a communication device according to Modification 3.

FIG. 7 is a flowchart illustrating a third example of the power supply voltage supply method according to the exemplary embodiment.

FIG. 8 is a view of the circuit configuration of an APT module and a communication device according to Modification 4.

FIG. 9 is a plan view of the communication device according to Modification 2.

FIG. 10A is a plan view of a first main surface of the APT module according to Modification 2.

FIG. 10B is a plan view of a second main surface of the APT module according to Modification 2.

### DETAILED DESCRIPTION OF EMBODIMENTS

Hereinafter, an exemplary embodiment of the present disclosure will be described in detail by using the drawings. The exemplary embodiment described below represents a comprehensive or specific example. Accordingly, a numerical value, a shape, a material, a component, the layout and connection form of the component, and the like that are described in the following embodiment are an example and are not intended to limit the present disclosure.

Each drawing is a schematic view appropriately subjected to emphasis, omission, or ratio control to describe the aspects of the exemplary embodiment, is not necessarily strictly illustrated, and has a shape, a positional relationship, and a ratio that are different from actual ones on occasions. Substantially the same components are denoted by the same reference numerals throughout the drawings and redundancy is omitted or simplified in some cases.

In the drawings below, an x axis and a y axis are axes orthogonal to each other on the plane parallel to the main surface of the module laminate. Specifically, when the module laminate is rectangular in a plan view, the x axis is parallel to first sides of the module laminate, and the y axis is parallel to second sides orthogonal to the first sides of the module laminate. Moreover, the z axis is perpendicular to the main surface of the module laminate, and the positive direction thereof represents an upward direction, and the negative direction represents a downward direction.

In the circuit configuration of the present disclosure, the term “connected” includes not only “directly connected” by using a connection terminal and/or a wiring conductor but also “electrically connected” with another circuit element interposed between one component and the other component”. In addition, the phrase “connected between A and B” denotes that a component is connected between A and B and to both of A and B and includes parallel connection (shunt connection) between the ground and a path connecting A and B in addition to series connection to the path.

In the component layout of the present disclosure, the phrase “a component is disposed on the substrate” includes disposition of the component on the main surface of the substrate and disposition of the component in the substrate. The phrase “a component is disposed on the main surface of a substrate” includes disposition of the component above the main surface without being in contact with the main surface (for example, the component is stacked on a different component disposed in contact with the main surface), in addition to disposition of the component in contact with the main surface of the substrate. In addition, the phrase “a component is disposed on the main surface of a substrate” may also include disposition of the component on a recessed portion formed in the main surface. The phrase “a component is disposed in the substrate” includes: encapsulation of the component in the module laminate; disposition of the entire component between main surfaces of the substrate and exposure of part of the component from the substrate; and disposition of only part of the component in the substrate.

In the component layout of the present disclosure, the term “plan view of a module laminate” denotes seeing an object or component orthographically projected on the xy plane from the positive z-axis direction side. The phrase “A is disposed between B and C” denotes that at least one of a plurality of lines connecting any point in B and any point in C passes through A. The phrase “a distance between A and B in plan view of a module laminate” denotes the length of a line connecting representative points in the respective regions of A and B that are orthographically projected on the xy plane. The center point in the region, a point closest to the region of the counterpart, or the like is usable as the representative point; however, the representative point is not limited to these.

Moreover, for purposes of this disclosure, the terms representing a relationship between elements such as “parallel” and “perpendicular”, a term representing the shape of an element such as “rectangular”, and a numerical value range indicate not only strict meaning but also inclusion of substantially the same range, for example, an error of approximately several percent.

In the component layout of the present disclosure, the phrase “a circuit element A and a circuit element B are disposed adjacently (or are adjacent to each other) denotes that in plan view of the module laminate, a different circuit element is not disposed between the circuit element A and the circuit element B.

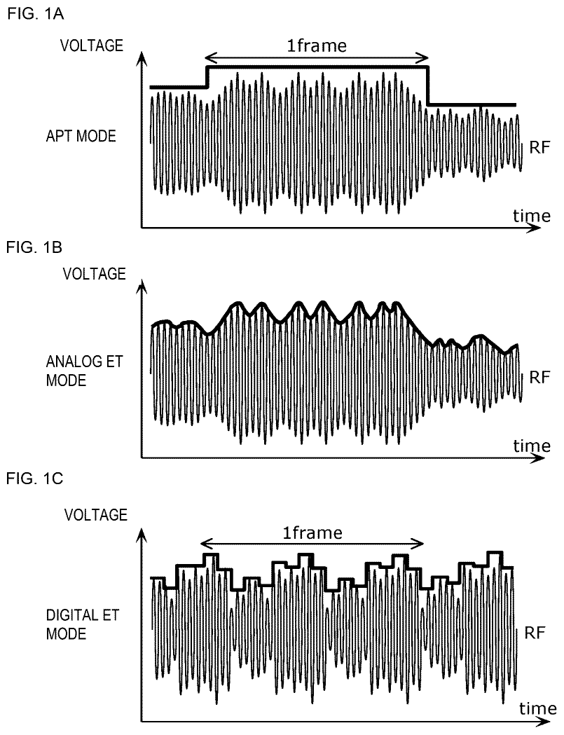

First, as technology for amplifying a radio frequency signal highly efficiently, a tracking mode in which a power supply voltage adjusted dynamically based on a radio frequency signal with the elapse of time is supplied to a power amplifier will be described. In general, the tracking mode is a mode in which a power supply voltage to be supplied to a power amplifier circuit is dynamically adjusted. There are some types of tracking modes, but an average power tracking (APT) mode and an envelope tracking (ET) mode (including an analog ET mode and a digital ET mode) are herein described with reference to FIGS. 1A to 1C. In each of FIGS. 1A to 1C, the horizontal axis represents time, and the vertical axis represents voltage. In addition, the thick solid line represents power supply voltage, and the thin solid line (e.g., a waveform) represents modulated signal.

FIG. 1A is a graph illustrating an example of power supply voltage changes in the APT mode. In the APT mode according to an exemplary aspect, the level of a power supply voltage is varied to a plurality of discrete voltage levels in units of one frame. As the result, a power supply voltage signal forms a rectangular wave. In the APT mode, the voltage level of the power supply voltage is determined based on an average output power. In the APT mode, the voltage level may vary in units smaller than one frame (for example, one subframe, one slot, or one symbol). It is noted that APT in which the voltage level varies in units of one symbol is also called symbol power tracking (SPT) in some cases.

For purposes of this disclosure, a frame serves as a unit of a radio frequency signal, is 10 milliseconds long, and includes 10 subframes. The subframe serves as a unit of a radio frequency signal, is one millisecond long, and includes two slots. A slot serves as a unit of a radio frequency signal, is 0.5 milliseconds long, and includes six symbols. A symbol serves as a unit of a radio frequency signal, is 71 milliseconds long, and includes a cyclic prefix (CP).

In the SPT mode, the level of the power supply voltage is modulated in units of one symbol. At this time, the voltage level is changed in the CP section. For example, the voltage level of a first symbol is changed to a higher voltage level in the CP, and the voltage level of a second symbol is changed to a lower voltage level in the CP. It is noted that the voltage level of a succeeding symbol does not change in another exemplary aspect. The level of the power supply voltage may can modulated based on a data signal in each symbol section.

In this disclosure, the APT mode includes the SPT mode, and the APT module includes a module that supplies a power supply voltage to a PA module in the SPT mode.

FIG. 1B is a graph illustrating an example of power supply voltage changes in the analog ET mode. The analog ET mode is an example of an ET mode in the related art. As illustrated in FIG. 1B, in the analog ET mode, the envelope of the modulated signal is tracked by continuously varying the power supply voltage. In the analog ET mode, the power supply voltage is determined based on an envelope signal.

An envelope signal is a signal indicating the envelope of the modulated signal. The envelope value is expressed by, for example, the square root of (I2+Q2). It is noted that (I, Q) represents a constellation point. A constellation point is a point at which a signal modulated by the digital modulation is represented in the constellation diagram. The point (I, Q) is determined, for example, by a baseband integrated circuit (BBIC) based on sending information.

FIG. 1C is a graph illustrating an example of power supply voltage changes in the digital ET mode. As illustrated in FIG. 1C, in the digital ET mode, the envelope of the modulated signal is tracked by varying the level of the power supply voltage to a plurality of discrete voltage levels in one frame. As the result, the power supply voltage signal forms a rectangular wave. In the digital ET mode, a power supply voltage level is selected or set from among the plurality of discrete voltage levels, based on the envelope signal.

### Exemplary Embodiment

### [1 Circuit Configuration of APT Module 1 and Communication Device 5]

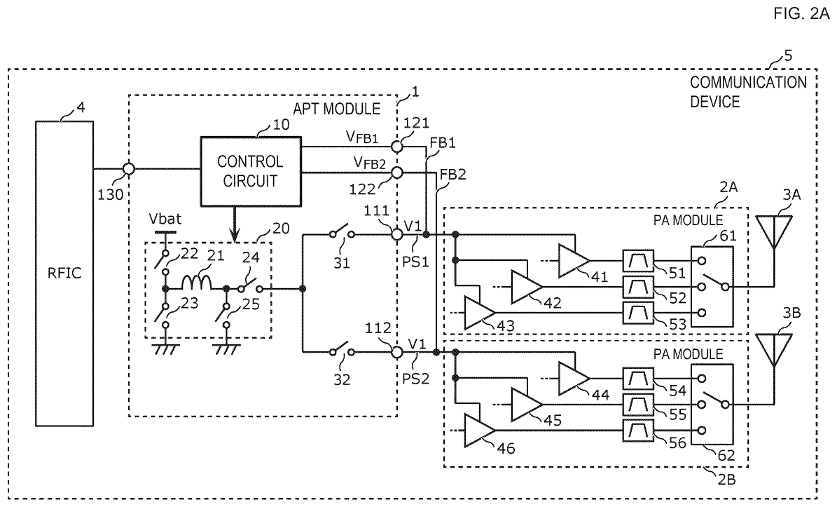

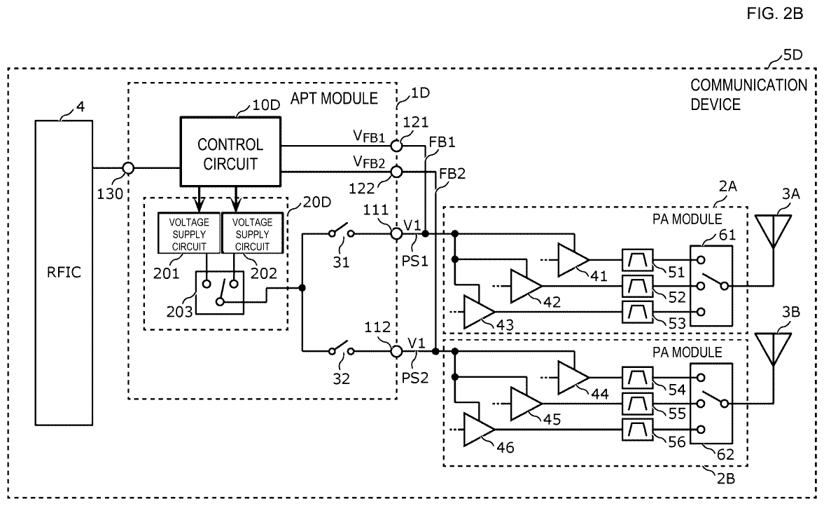

An average power tracking module (hereinafter, referred to as an APT module) 1 and a communication device 5 according to this embodiment will be described with reference to FIG. 2A.

FIG. 2A is a view of the circuit configuration of the APT module 1 and the communication device 5 according to the exemplary embodiment. The communication device 5 according to this embodiment corresponds to a user terminal (UE: User Equipment) in a cellular network and is typically a mobile phone, a smartphone, a tablet computer, a wearable device, or the like. The communication device 5 may be an internet of things (IoT) sensor device, a medical/health care device, a vehicle, an unmanned aerial vehicle (UAV) (so-called a drone), or an automated guided vehicle (AGV).

First, the circuit configuration of the communication device 5 will be described. As illustrated in FIG. 2A, the communication device 5 according to this embodiment includes the APT module 1, PA modules 2A and 2B, antennas 3A and 3B, and a radio frequency integrated circuit (RFIC) 4.

The antenna 3A is connected to the PA module 2A and sends the radio frequency signal output from the PA module 2A. The antenna 3B is connected to the PA module 2B and sends the radio frequency signal output from the PA module 2B. The antennas 3A and 3B may be formed as one antenna, and in this case, the PA modules 2A and 2B are connected to a common antenna.

For purposes of this disclosure, the RFIC 4 is an example of a signal processing circuit that is configured to process a radio frequency signal. The RFIC 4 has a controller that is configured to control the PA modules 2A and 2B. Specifically, the RFIC 4 performs the signal processing by performing upconverting or the like of a sending signal input from the BBIC (not illustrated) and outputs, to the PA modules 2A and 2B, a radio frequency sending signal generated by the signal processing. The RFIC 4 also is configured to output a digital control signal for controlling the APT module 1 to the APT module 1. Part or entirety of the function of the RFIC 4 as a controller may be implemented outside the RFIC 4 and may be implemented on, for example, the BBIC, the PA modules 2A and 2B, or the APT module 1.

In an exemplary aspect, the APT module 1 is configured to supply a power supply voltage V1 to the PA modules 2A and 2B in the APT mode. The power supply voltage V1 is an example of a first voltage. As described with reference to FIG. 1A, in the APT mode, the level of the power supply voltage V1 is varied to the plurality of discrete voltage levels in units of one frame, based on the average output power of the power amplifier. As illustrated in FIG. 2A, the APT module 1 includes a converter circuit 20, a control circuit 10, switches 31 and 32, output terminals 111 and 112, feedback (hereinafter, referred to as FB) terminals 121 and 122, and a control signal terminal 130.

The converter circuit 20 generates the power supply voltage V1 in response to a control signal output from the control circuit 10 and outputs the power supply voltage V1 to the output terminals 111 and 112. The converter circuit 20 includes, for example, an inductor 21 and switches 22, 23, 24, and 25. Through on/off control of the switches 22 to 25, the converter circuit 20 increases or decreases magnetic energy generated at the inductor 21 and outputs the magnetic energy as the power supply voltage V1. The inductor 21 may be disposed outside the APT module 1.

The output terminal 111 is an example of a first output terminal that is an external connection terminal. The output terminal 111 is connected to the converter circuit 20 with the switch 31 interposed therebetween and is also connected to the PA module 2A, and the power supply voltage V1 generated by the converter circuit 20 is applied thereto. The output terminal 112 is an example of a second output terminal that is an external connection terminal. The output terminal 112 is connected to the converter circuit 20 with the switch 32 interposed therebetween and is also connected to the PA module 2B, and the power supply voltage V1 generated by the converter circuit 20 is applied thereto.

The FB terminal 121 is an example of a first feedback terminal that is an external connection terminal. The FB terminal 121 is connected to a signal path PS1 connecting the output terminal 111 and power amplifiers 41 to 43 of the PA module 2A and is also connected to the control circuit 10. The FB terminal 122 is an example of a second feedback terminal that is an external connection terminal. The FB terminal 122 is connected to a signal path PS2 connecting the output terminal 112 and power amplifiers 44 to 46 of the PA module 2B and is also connected to the control circuit 10.

The control signal terminal 130 is connected to the RFIC 4 and the control circuit 10.

The control circuit 10 is an example of a controller of the APT module 1 and is connected to the FB terminals 121 and 122 and the converter circuit 20. The control circuit 10 controls the on/off timing of the switches 22 to 25 of the converter circuit 20 to cause the power supply voltage V1 to be output from the converter circuit 20 based on target power supply voltage information for the PA modules 2A and 2B input from the RFIC 4 via the control signal terminal 130 and FB power supply voltages input via the FB terminals 121 and 122.

The switch 31 is an example of a first switch, is connected between the converter circuit 20 and the output terminal 111 and performs switching between connection and non-connection between the converter circuit 20 and the output terminal 111. The switch 32 is an example of a second switch, is connected between the converter circuit 20 and the output terminal 112 and performs switching between connection and non-connection between the converter circuit 20 and the output terminal 112. The switches 31 and 32 are allowed to conduct simultaneously. When the PA module 2A and the PA module 2B simultaneously execute transmission of radio frequency sending signals, the switches 31 and 32 both enter into a connection state, and the power supply voltage V1 is simultaneously supplied to both of the PA modules 2A and 2B.

The switches 31 and 32 are not included in an alternative aspect. In this case, the power supply voltage V1 generated by the converter circuit 20 are always supplied to the PA modules 2A and 2B.

With the configuration described above of the APT module 1, when the PA module 2A and the PA module 2B simultaneously execute transmission of radio frequency sending signals, the same power supply voltage V1 is supplied from the APT module 1 to each of the PA modules 2A and 2B at a predetermined time. That is, the APT module 1 does not supply a plurality of different power supply voltages at the same time in an exemplary aspect, and thus the circuit configuration may be simplified. The small APT module 1 can thus be configured to simultaneously supply the power supply voltage V1 to the power amplifiers 41 to 46.

The APT module 1 according to this embodiment is applicable as an APT circuit. That is, the APT circuit according to this embodiment includes the converter circuit 20 that outputs the power supply voltage V1, the switch 31 disposed on a first path that connects the converter circuit 20 and the power amplifiers 41 to 43 and through which the power supply voltage V1 is supplied to the power amplifiers 41 to 43, and the switch 32 disposed on a second path that connects the converter circuit 20 and the power amplifiers 44 to 46 and through which the power supply voltage V1 is supplied to the power amplifiers 44 to 46, and the switch 31 and the switch 32 are allowed to conduct simultaneously.

With the configuration described above of the APT circuit, when the switches 31 and 32 simultaneously enter into the conduction state, the same power supply voltage V1 is supplied from the APT circuit to each of the PA modules 2A and 2B. That is, the APT circuit does not supply the plurality of different power supply voltages in an exemplary aspect, and thus the circuit configuration is simplified. The small and simplified APT circuit can thus be configured to simultaneously supply the power supply voltage V1 to the power amplifiers 41 to 46.

In response to the supply of the power supply voltage V1 from the APT module 1 in the APT mode, the PA module 2A amplifies the radio frequency sending signal input from the RFIC 4 and outputs the radio frequency sending signal to the antenna 3A. The PA module 2A includes the power amplifiers 41, 42, and 43, filters 51, 52, and 53, and a switch 61.

According to an exemplary aspect, each of the power amplifiers 41 to 43 is an example of a first power amplifier and is connected between the APT module 1 and the antenna 3A. Specifically, the power terminal of the power amplifier 41 is connected to the APT module 1, a radio frequency input terminal thereof is connected to the RFIC 4, and a radio frequency output terminal thereof is connected to the antenna 3A with the filter 51 and the switch 61 interposed therebetween. The power terminal of the power amplifier 42 is connected to the APT module 1, a radio frequency input terminal thereof is connected to the RFIC 4, and a radio frequency output terminal thereof is connected to the antenna 3A with the filter 52 and the switch 61 interposed therebetween. The power terminal of the power amplifier 43 is connected to the APT module 1, a radio frequency input terminal thereof is connected to the RFIC 4, and a radio frequency output terminal thereof is connected to the antenna 3A with the filter 53 and the switch 61 interposed therebetween. The power amplifier 41 can be configured to amplify a radio frequency signal in Band A, the power amplifier 42 can be configured to amplify a radio frequency signal in Band B, and the power amplifier 43 can be configured to amplify a radio frequency signal in Band C.

The filter 51 has a pass band including, for example, Band A. The filter 52 has a pass band including, for example, Band B. The filter 53 has a pass band including, for example, Band C.

The switch 61 has a common terminal and three selection terminals and performs switching of connection between the common terminal and one of the three selection terminals. The common terminal of the switch 61 is connected to the antenna 3A, a first selection terminal is connected to the filter 51, a second selection terminal is connected to the filter 52, and a third selection terminal is connected to the filter 53.

With the configuration described above of the PA module 2A, the PA module 2A can be configured to amplify a radio frequency signal in one of Band A, Band B, and Band C and outputting the radio frequency signal to the antenna 3A.

A node on the signal path PS1 connecting the power terminals of the power amplifiers 41 to 43 and the output terminal 111 and the FB terminal 121 are connected by using a FB line FB1.

In response to the supply of the power supply voltage V1 from the APT module 1 in the APT mode, the PA module 2B amplifies the radio frequency sending signal input from the RFIC 4 and outputs the radio frequency sending signal to the antenna 3B. The PA module 2B includes the power amplifiers 44, 45, and 46, filters 54, 55, and 56, and a switch 62.

According to an exemplary aspect, each of the power amplifiers 44 to 46 is an example of a second power amplifier and is connected between the APT module 1 and the antenna 3B. Specifically, the power terminal of the power amplifier 44 is connected to the APT module 1, a radio frequency input terminal thereof is connected to the RFIC 4, and a radio frequency output terminal thereof is connected to the antenna 3B with the filter 54 and the switch 62 interposed therebetween. The power terminal of the power amplifier 45 is connected to the APT module 1, a radio frequency input terminal thereof is connected to the RFIC 4, and a radio frequency output terminal thereof is connected to the antenna 3B with the filter 55 and the switch 62 interposed therebetween. The power terminal of the power amplifier 46 is connected to the APT module 1, a radio frequency input terminal thereof is connected to the RFIC 4, and a radio frequency output terminal thereof is connected to the antenna 3B with the filter 56 and the switch 62 interposed therebetween. The power amplifier 44 can be configured to amplify a radio frequency signal in Band D, the power amplifier 45 can be configured to amplify a radio frequency signal in Band E, and the power amplifier 46 can be configured to amplify a radio frequency signal in Band F.

The filter 54 has a pass band including, for example, Band D. The filter 55 has a pass band including, for example, Band E. The filter 56 has a pass band including, for example, Band F.

The switch 62 has a common terminal and three selection terminals and performs switching of connection between the common terminal and one of the three selection terminals. The common terminal of the switch 62 is connected to the antenna 3B, a first selection terminal is connected to the filter 54, a second selection terminal is connected to the filter 55, and a third selection terminal is connected to the filter 56.

With the configuration described above of the PA module 2B, the PA module 2B can be configured to amplify a radio frequency signal in one of Band D, Band E, and Band F and outputting the radio frequency signal to the antenna 3B.

A node on the signal path PS2 connecting the power terminals of the power amplifiers 44 to 46 and the output terminal 112 and the FB terminal 122 are connected by using a FB line FB2.

Each of the PA modules 2A and 2B is only required to have at least one power amplifier.

The circuit configuration of the communication device 5 illustrated in FIG. 2A is an example and is not limited to this. For example, the communication device 5 does not include the antennas 3A and 3B in an alternative aspect.

In the configuration described above, a radio frequency signal transmitted through the PA module 2A is, for example, a Sub6 signal in a cellular network, and a radio frequency signal transmitted through the PA module 2B is, for example, a Sub6 signal in a cellular network (Inter-band UL CA). The radio frequency signal transmitted through the PA module 2A is, for example, a Sub6 signal in a cellular network, and the radio frequency signal transmitted through the PA module 2B is, for example, a signal in a 28 GHz band (Inter-band UL CA). The radio frequency signal transmitted through the PA module 2A is, for example, a signal in the 28 GHz band, and the radio frequency signal transmitted through the PA module 2B is, for example, a signal in the 28 GHz band (Inter-band UL CA). The radio frequency signal transmitted through the PA module 2A is a signal in LTE Advanced, and the radio frequency signal transmitted through the PA module 2B is, for example, a signal in LTE Advanced (Intra-band Contiguous CA, Inter-band Non-contiguous CA, Intra-band Non-contiguous CA).

The APT module 1 may supply a power supply voltage to the PA modules 2A and 2B in the SPT mode.

FIG. 2B is a view of the circuit configuration of an APT module 1D and a communication device 5D according to Modification 1. As illustrated in FIG. 2B, the communication device 5D according to this modification includes the APT module 1D, the PA modules 2A and 2B, the antennas 3A and 3B, and the RFIC 4. The communication device 5D according to this modification is different in only the configuration of the APT module 1D as compared with the communication device 5 according to the embodiment. Hereinafter, the communication device 5D according to this modification will be described, focusing on the configuration of the APT module 1D.

The APT module 1D includes a converter circuit 20D, a control circuit 10D, the switches 31 and 32, the output terminals 111 and 112, the FB terminals 121 and 122, and the control signal terminal 130.

In response to a control signal output from the control circuit 10D, the converter circuit 20D is configured to generate the power supply voltage V1 in the SPT mode and outputs the power supply voltage V1 to the output terminals 111 and 112. The power supply voltage V1 includes a plurality of discrete voltages in one frame period of a radio frequency signal. The converter circuit 20D includes voltage supply circuits 201 and 202 and a switch 203.

In an exemplary aspect, the control circuit 10D is an example of a controller of the APT module 1D and is connected to the FB terminals 121 and 122 and the converter circuit 20D. The control circuit 10D can be configured to control the voltage supply circuits 201 and 202 and the switch 203 to cause the power supply voltage V1 to be output from the converter circuit 20D based on the target power supply voltage information for the PA modules 2A and 2B input from the RFIC 4 via the control signal terminal 130 and the FB power supply voltages input via the FB terminals 121 and 122. For example, the control circuit 10D can be configured to receive a digital control signal from the RFIC 4 and providing the respective voltage supply circuits 201 and 202 with a first voltage level control signal and a second voltage level control signal indicating the voltage levels of symbols. Further, the control circuit 10D is configured to provide the switch 203 with a switching control signal.

The voltage supply circuit 201 can be configured to generate the power supply voltage V1 based on the first voltage level control signal received from the control circuit 10D. At this time, the voltage supply circuit 201 can be configured to change the level of the power supply voltage V1 for each symbol for the voltage supply circuit 201, based on the first voltage level control signal.

The voltage supply circuit 202 can be configured to generate the power supply voltage V1 based on the second voltage level control signal received from the control circuit 10D. At this time, the voltage supply circuit 202 can be configured to change the level of the power supply voltage V1 for each symbol for the voltage supply circuit 202, based on the second voltage level control signal.

Based on the switching control signal, the switch 203 can be configured to alternately select one of the voltage supply circuits 201 and 202 for each symbol and connecting the selected voltage supply circuit to the PA modules 2A and 2B. This configuration enables the switch 203 to supply the power supply voltage V1 modulated in the SPT mode to the PA modules 2A and 2B.

In an exemplary aspect, the converter circuit 20D can include a magnetic regulation stage, a switched capacitor voltage balancer stage, or at least one output switching stage, instead of the voltage supply circuits 201 and 202 and the switch 203.

With the configuration described above of the APT module 1D, when the PA module 2A and the PA module 2B simultaneously execute transmission of radio frequency sending signals, the same power supply voltage V1 is supplied from the APT module 1D to each of the PA modules 2A and 2B. That is, the APT module 1D does not supply the plurality of different power supply voltages at the same time in an exemplary aspect, and thus the circuit configuration is simplified. The small APT module 1D configured to simultaneously supply the power supply voltage V1 to the power amplifiers 41 to 46 may thus be provided.

### [2 Method for Supplying Power Supply Voltage to APT Module 1 According to Embodiment]

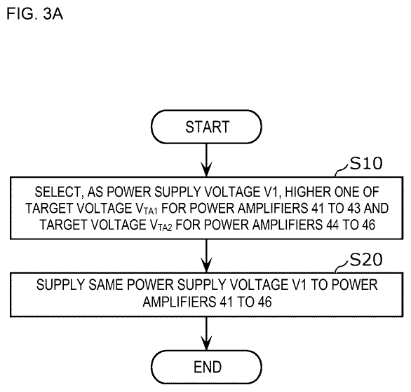

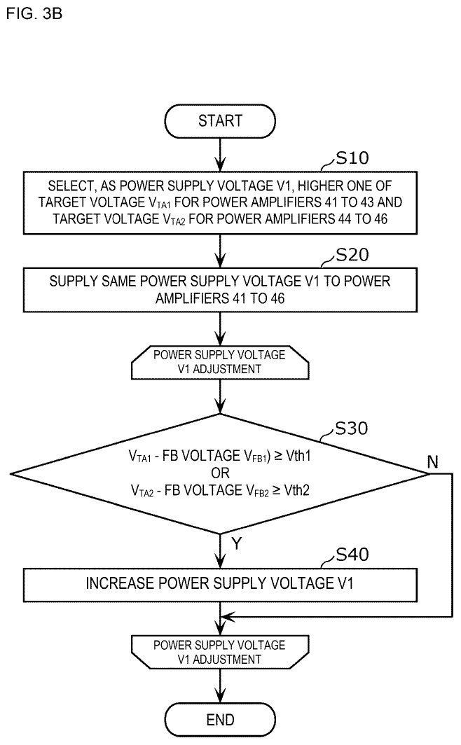

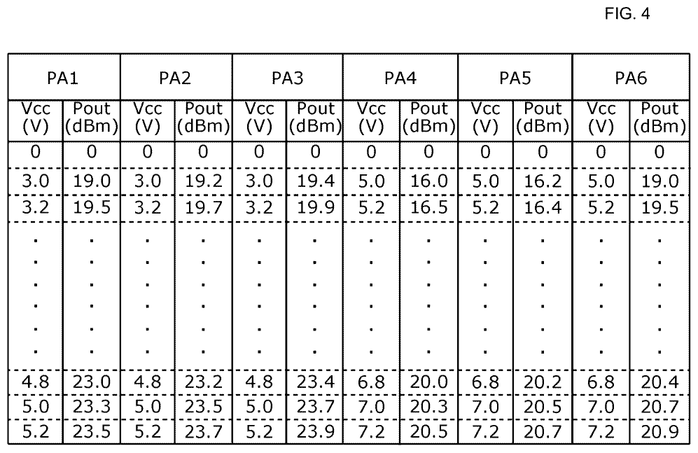

A method for supplying a power supply voltage to the two PA modules 2A and 2B by the APT module 1 configured as described above will then be described with reference to FIGS. 3A, 3B, and 4. FIG. 3A is a flowchart illustrating a first example of the power supply voltage supply method according to the embodiment.

First, the APT module 1 is configured to select, as the power supply voltage V1, a higher voltage of a target voltage V_{TA1} for the PA module 2A (power amplifiers 41 to 43) and a target voltage V_{TA2} for the PA module 2B (power amplifiers 44 to 46) (S10). In step S10, for example, the control circuit 10 selects the higher voltage of the target voltages V_{TA1} and V_{TA2} as the power supply voltage V1 based on information regarding the target voltages V_{TA1} and V_{TA2} input via the control signal terminal 130.

A target voltage for a power amplifier is an optimum power supply voltage to be applied to output desired output power from the power amplifier.

The APT module 1 then supplies the same power supply voltage V1 to the PA modules 2A and 2B (power amplifiers 41 to 46) (S20). In step S20, for example, the converter circuit 20 outputs the power supply voltage V1 to the output terminals 111 and 112 in response to the switches 31 and 32 entering into the conduction state after on/off operations of the switches 22 to 25 are performed under the control of the control circuit 10.

That is, the control circuit 10 is configured to cause the converter circuit 20 to output, as the power supply voltage V1 at a predetermined time, a higher one of the target voltage V_{TA1} (e.g., a first power supply voltage) and the target voltage V_{TA2} (e.g., a second power supply voltage). The target voltage V_{TA1} is to be supplied to the power amplifiers 41 to 43 at the predetermined time based on the output power of the power amplifiers 41 to 43, and the target voltage V_{TA2} is to be supplied to the power amplifiers 44 to 46 at the predetermined time based on the output power of the power amplifiers 44 to 46.

This configuration enables the APT module 1 to supply the power supply voltage V1 appropriate for the power amplifiers 41 to 46 to perform appropriate amplification operations.

FIG. 3B is a flowchart illustrating a second example of the power supply voltage supply method according to the embodiment. The second example of the power supply voltage supply method illustrated in the figure is different in that steps for the control circuit 10 to adjust the power supply voltage V1 are added, as compared with the first example of the power supply voltage supply method illustrated in FIG. 3A. The description of the same points of the second example of the power supply voltage supply method according to the embodiment as those of the first example of the power supply voltage supply method according to the embodiment are hereinafter omitted, and the different point is described.

Steps S10 to S20 are the same as those in the first example of the power supply voltage supply method according to the embodiment.

The APT module 1 then determines whether a first differential voltage obtained by subtracting a FB voltage V_{FB1} across the FB terminal 121 from the target voltage V_{TA1} (first power supply voltage) is higher than or equal to a first threshold (Vth1) or whether a second differential voltage obtained by subtracting a FB voltage V_{FB2} across the FB terminal 122 from the target voltage V_{TA2} (second power supply voltage) is higher than or equal to a second threshold (Vth2) (S30).

In step S30, the APT module 1 is configured to increase the power supply voltage V1 (S40) when the first differential voltage is higher than or equal to Vth1, or when the second differential voltage is higher than or equal to Vth2, (Y in S30).

Steps S30 and S40 (e.g., a power supply voltage V1 adjustment loop) are performed for a predetermined period. The predetermined period may be appropriately decided depending on the usage status of the communication device 5. For example, the predetermined period may be a period in which the communication device 5 is operating or may be a period lasting until the first differential voltage becomes lower than Vth1 and the second differential voltage becomes lower than Vth2.

The higher the differential voltage described above, the more the consumption of the power supply voltage V1 across each of the power amplifiers 41 to 46. For example, assume that in step S10, the power supply voltage V1=5.0 V is determined based on the target voltage V_{TA1}=5.0 V and the target voltage V_{TA2}=4.0 V. Also assume that, in step S30, the FB voltage V_{FB1}=4.8 V and the FB voltage V_{FB2}=3.2 V. At this time, V_{TA1}−V_{FB1}=0.2 V and V_{TA2}−V_{FB2}=0.8 V hold true. That is, the power supply voltage consumption at the power amplifiers 44 to 46 is higher than the power supply voltage consumption at the power amplifiers 41 to 43. Since (V_{TA2}−V_{FB2}) is higher than or equal to Vth2 where Vth1=Vth2=0.5 V, the control circuit 10 increases the power supply voltage V1 (for example, V1=5.2 V).

That is, the control circuit 10 is configured to increase the power supply voltage V1 when the differential voltage obtained by subtracting the FB voltage V_{FB1} across the FB terminal 121 from the target voltage V_{TA1} is higher than or equal to Vth1, or when the differential voltage obtained by subtracting the FB voltage V_{FB2} across the FB terminal 122 from the target voltage V_{TA2} is higher than or equal to Vth2.

This configuration enables the APT module 1 to supply the power supply voltage V1 for the power amplifiers 41 to 46 to perform appropriate amplification operations according to an amplification state change in the power amplifiers 41 to 46.

In an exemplary aspect, the APT module 1 includes a memory configured to store, in advance, correlation data indicating a relationship between power supply voltages to be supplied to the power amplifiers 41 to 46 and output power. The memory may also be, for example, a lookup table (hereinafter, referred to as a LUT).

FIG. 4 is a view illustrating an example of a LUT of the APT module 1 according to the embodiment. The figure illustrates a LUT having data regarding correlation between power supply voltages Vcc (V) to be supplied to the power amplifiers 41 (PA1), 42 (PA2), 43 (PA3), 44 (PA4), 45 (PA5), and 46 (PA6) and output power Pout (dBm).

The control circuit 10 can be configured to estimate the sum of the output power of the power amplifiers 41 to 46 based on the power supply voltage V1 and correlation data listed in the LUT and control the power supply voltage V1 to prevent the sum from exceeding a third threshold (Pth3). Pth3 is based on, for example, the maximum antenna power regulation. The maximum antenna power is, for example, 23 dBm in the regulation.

This configuration enables the APT module 1 to supply the power supply voltage V1 for the power amplifiers 41 to 46 to perform appropriate amplification operations and also meet restrictions on the power of the radio frequency signal output from the communication device 5.

### [3 Circuit Configuration of APT Modules 1A and 1 and Communication Devices 5A and 5B]

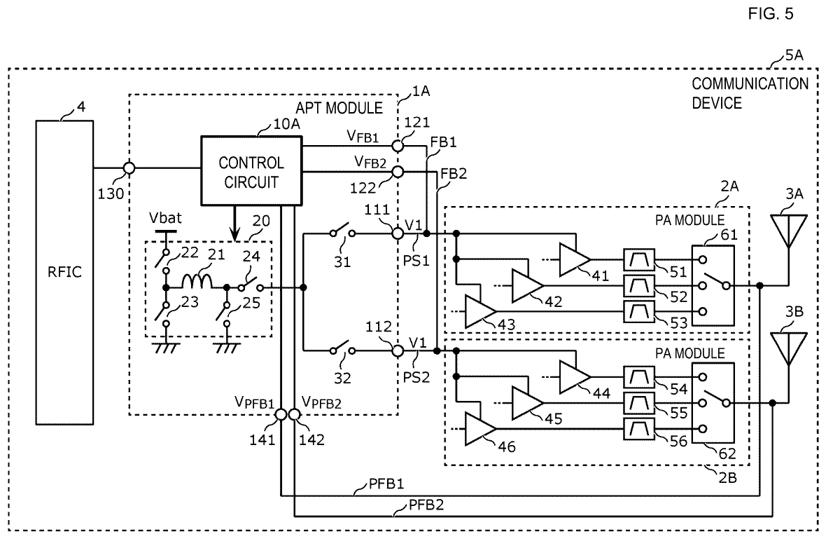

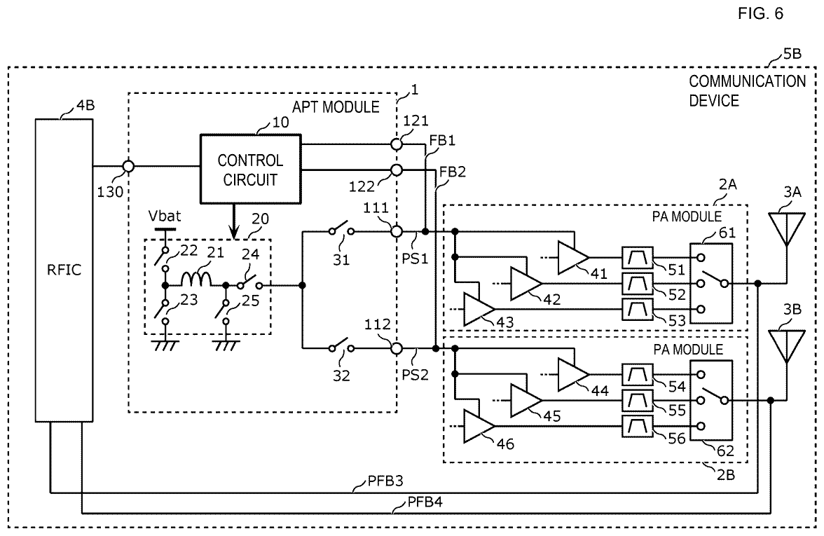

An APT module 1A and a communication device 5A according to Modification 2 and the APT module 1 and a communication device 5B according to Modification 3 will then be described with reference to FIGS. 5 and 6.

FIG. 5 is a view of the circuit configuration of the APT module 1A and the communication device 5A according to Modification 2. As illustrated in the figure, the communication device 5A according to Modification 2 includes the APT module 1A, the PA modules 2A and 2B, the antennas 3A and 3B, and the RFIC 4. The communication device 5A according to this modification is different in that output power feedback lines are disposed, as compared with the communication device 5 according to the embodiment. Hereinafter, the communication device 5A according to this modification will be described, focusing on the difference from the communication device 5 according to the embodiment.

The APT module 1A includes the converter circuit 20, a control circuit 10A, the switches 31 and 32, the output terminals 111 and 112, the FB terminals 121 and 122, the control signal terminal 130, and output power feedback (hereinafter, referred to as output power FB) terminals 141 and 142. The APT module 1A according to this modification is different in that the output power FB terminals 141 and 142 are disposed and how the control circuit 10A performs control, as compared with the APT module 1 according to the embodiment. Hereinafter, the APT module 1A according to this modification will be described, focusing on the differences from the APT module 1 according to the embodiment.

The output power FB terminal 141 is an example of a third feedback terminal that is an external connection terminal. The output power FB terminal 141 is connected to a node on a signal path connecting the PA module 2A and the antenna 3A via an output power FB line PFB1 and is also connected to the control circuit 10A. In other words, the output power FB terminal 141 is connected to respective signal output ports of the power amplifiers 41 to 43. The output power FB terminal 142 is an example of a fourth feedback terminal that is an external connection terminal. The output power FB terminal 142 is connected to a node on a signal path connecting the PA module 2B and the antenna 3B via an output power FB line PFB2 and is also connected to the control circuit 10A. In other words, the output power FB terminal 142 is connected to respective signal output ports of the power amplifiers 44 to 46.

The control circuit 10A is an example of a controller of the APT module 1A and is connected to the FB terminals 121 and 122, the output power FB terminals 141 and 142, and the converter circuit 20. The control circuit 10A controls the on/off timing of the switches 22 to 25 of the converter circuit 20 to cause the power supply voltage V1 to be output from the converter circuit 20 based on the target power supply voltage information for the PA modules 2A and 2B input from the RFIC 4 via the control signal terminal 130, the FB power supply voltages input via the FB terminals 121 and 122, and the output power of the power amplifiers 41 to 46 input via the output power FB terminals 141 and 142.

With the configuration described above of the APT module 1A, when the PA module 2A and the PA module 2B simultaneously execute transmission of radio frequency sending signals, the same power supply voltage V1 is supplied from the APT module 1A to each of the PA modules 2A and 2B. That is, the APT module 1A does not supply the plurality of different power supply voltages in the exemplary aspect, and thus the circuit configuration is simplified. The small APT module 1A can thus be provided that is configured to simultaneously supply the power supply voltage V1 to the power amplifiers 41 to 46.

FIG. 6 is a view of the circuit configuration of the APT module 1 and the communication device 5B according to Modification 3. As illustrated in the figure, the communication device 5B according to Modification 3 includes the APT module 1, the PA modules 2A and 2B, the antennas 3A and 3B, and a RFIC 4B. The communication device 5B according to this modification is different in that output power feedback lines are disposed, as compared with the communication device 5 according to the embodiment. Hereinafter, the communication device 5B according to this modification will be described, focusing on the difference from the communication device 5 according to the embodiment.

An output power FB line PFB3 is connected between the RFIC 4B and a node on a signal path connecting the PA module 2A and the antenna 3A. In addition, an output power FB line PFB4 is connected between the RFIC 4B and a node on a signal path connecting the PA module 2B and the antenna 3B.

### [4 Method for Supplying Power Supply Voltage Performed by APT Module According to Modification]

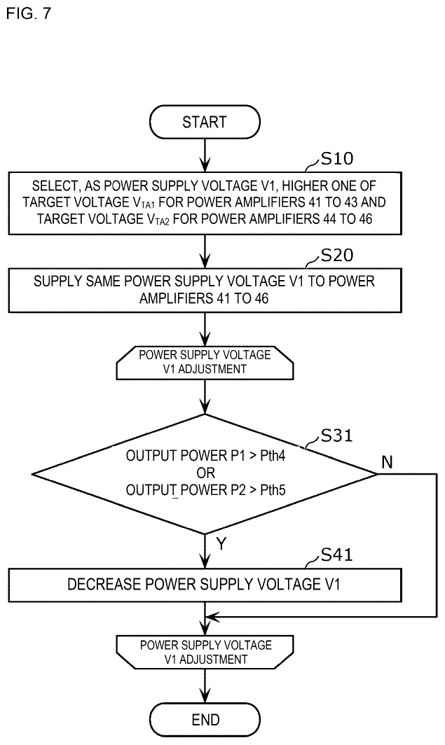

A method for supplying a power supply voltage to the two PA modules 2A and 2B by the APT module 1A and a method for supplying a power supply voltage to the two PA modules 2A and 2B by the APT module 1 will be described with reference to FIG. 7. FIG. 7 is a flowchart illustrating a third example of the power supply voltage supply method according to the exemplary embodiment. The power supply voltage supply method illustrated in the figure is different in that steps for the control circuit 10 (or 10A) to adjust the power supply voltage V1 are added, as compared with the first example of the power supply voltage supply method illustrated in FIG. 3A. Hereinafter, the description of the same points of the third example of the power supply voltage supply method as those of the first example of the power supply voltage supply method are hereinafter omitted, and the different point is described.

Steps S10 to S20 are the same as those in the first example of the power supply voltage supply method according to the embodiment.

The APT module 1 (or 1A) then determines whether the output power of the power amplifiers 41 to 43 exceeds a fourth threshold (Pth4) or whether the output power of the power amplifiers 44 to 46 exceeds a fifth threshold (Pth5) (S31).

In step S31, the APT module 1 (or 1A) decreases the power supply voltage V1 (S41) when the output power of the power amplifiers 41 to 43 exceeds Pth4, or when the output power of the power amplifiers 44 to 46 exceeds Pth5 (Y in S31).

Steps S31 and S41 (e.g., a power supply voltage V1 adjustment loop) are performed for a predetermined period. The predetermined period may be appropriately decided depending on the usage status of the communication device 5. For example, the predetermined period may be a period in which the communication device 5 is operating or may be a period lasting until the first differential power obtained by subtracting the output power of the power amplifiers 41 to 43 from Pth4 becomes higher than or equal to a sixth threshold (Pth6) and the second differential power obtained by subtracting the output power of the power amplifiers 44 to 46 from Pth5 becomes higher than or equal to a seventh threshold (Pth7).

That is, in the APT module 1A according to Modification 2, the control circuit 10A decreases the power supply voltage V1 when the power value detected at the output power FB terminal 141 exceeds Pth4 or when the power value detected at the output power FB terminal 142 exceeds Pth5.

In the APT module 1 according to Modification 3, the control circuit 10 decreases the power supply voltage V1 when the output power of the radio frequency signal detected at the RFIC 4B via the output power FB line PFB3 exceeds Pth4 or when the output power of the radio frequency signal detected at the RFIC 4B via the output power FB line PFB4 exceeds Pth5.

The higher the output power of the power amplifiers 41 to 46, the higher a distortion component due to a non-linear form. It is thus assumed that the quality of a radio frequency sending signal output from the communication device 5A or 5B does not satisfy the specified quality.

In contrast, according to the above-described third example of the power supply voltage supply method, in the APT module 1 or 1A according to the modification, signal distortion is prevented according to the magnitude of the output power of the power amplifiers 41 to 46, and the power supply voltage V1 appropriate for the power amplifiers 41 to 46 to perform appropriate amplification operations may be provided.

### [5 Circuit Configuration of APT Module 1C and Communication Device 5C]

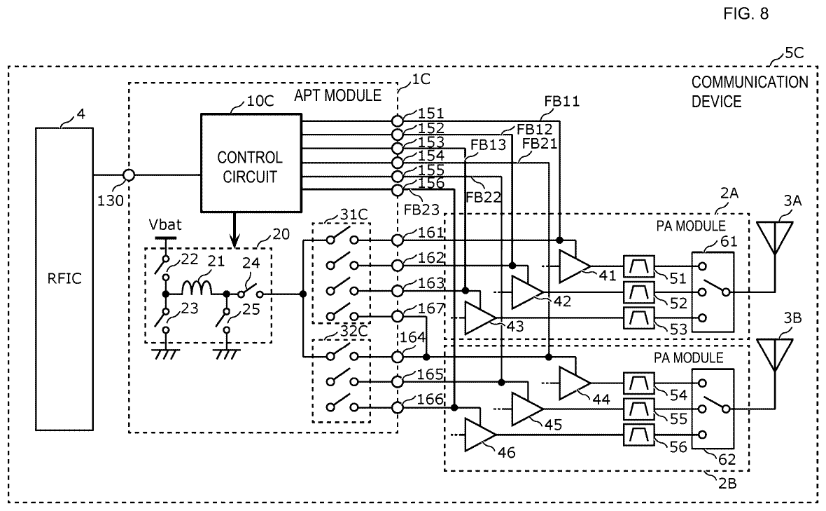

An APT module 1C and a communication device 5C according to Modification 4 will then be described with reference to FIG. 8.

FIG. 8 is a view of the circuit configuration of the APT module 1C and the communication device 5C according to Modification 4. As illustrated in the figure, the communication device 5C according to Modification 4 includes the APT module 1C, the PA modules 2A and 2B, the antennas 3A and 3B, and the RFIC 4. The communication device 5B according to this modification is different in the configuration of the APT module 1C, as compared with the communication device 5 according to the embodiment. Hereinafter, the communication device 5C according to this modification will be described, focusing on the difference from the communication device 5 according to the embodiment.

The APT module 1C includes the converter circuit 20, a control circuit 10C, switches 31C and 32C, output terminals 161, 162, 163, 164, 165, 166, and 167, FB terminals 151, 152, 153, 154, 155, and 156, and the control signal terminal 130. The APT module 1C according to this modification is different in the configuration of the output terminal and the FB terminal, as compared with the APT module 1 according to the embodiment. Hereinafter, the APT module 1C according to this modification will be described, focusing on the difference from the APT module 1 according to the embodiment.

The output terminal 161 is an example of the first output terminal. The output terminal 161 is connected to the converter circuit 20 with the switch 31C interposed therebetween and is also connected to the power amplifier 41, and the power supply voltage V1 generated by the converter circuit 20 is applied thereto. The output terminal 162 is an example of the first output terminal. The output terminal 162 is connected to the converter circuit 20 with the switch 31C interposed therebetween and is also connected to the power amplifier 42, and the power supply voltage V1 generated by the converter circuit 20 is applied thereto. The output terminal 163 is an example of the first output terminal. The output terminal 163 is connected to the converter circuit 20 with the switch 31C interposed therebetween and is also connected to the power amplifier 43, and the power supply voltage V1 generated by the converter circuit 20 is applied thereto. The output terminal 164 is an example of the second output terminal. The output terminal 164 is connected to the converter circuit 20 with a switch 32C interposed therebetween and is also connected to the power amplifier 44, and the power supply voltage V1 generated by the converter circuit 20 is applied thereto. The output terminal 165 is an example of the second output terminal. The output terminal 165 is connected to the converter circuit 20 with the switch 32C interposed therebetween and is also connected to the power amplifier 45, and the power supply voltage V1 generated by the converter circuit 20 is applied thereto. The output terminal 166 is an example of the second output terminal. The output terminal 166 is connected to the converter circuit 20 with the switch 32C interposed therebetween and is also connected to the power amplifier 46, and the power supply voltage V1 generated by the converter circuit 20 is applied thereto. The output terminal 167 is an example of the second output terminal. The output terminal 167 is connected to the converter circuit 20 with the switch 31C interposed therebetween and is also connected to the power amplifier 44, and the power supply voltage V1 generated by the converter circuit 20 is applied thereto.

The FB terminal 151 is an example of the first feedback terminal. The FB terminal 151 is connected to a signal path connecting the power amplifier 41 and the output terminal 161 and is also connected to the control circuit 10C. The FB terminal 152 is an example of the first feedback terminal. The FB terminal 152 is connected to a signal path connecting the power amplifier 42 and the output terminal 162 and is also connected to the control circuit 10C. The FB terminal 153 is an example of the first feedback terminal. The FB terminal 153 is connected to a signal path connecting the power amplifier 43 and the output terminal 163 and is also connected to the control circuit 10C. The FB terminal 154 is an example of the second feedback terminal. The FB terminal 154 is connected to a signal path connecting the power amplifier 44 and the output terminal 164 and is also connected to the control circuit 10C. The FB terminal 155 is an example of the second feedback terminal. The FB terminal 155 is connected to a signal path connecting the power amplifier 45 and the output terminal 165 and is also connected to the control circuit 10C. The FB terminal 156 is an example of the second feedback terminal. The FB terminal 156 is connected to a signal path connecting the power amplifier 46 and the output terminal 166 and is also connected to the control circuit 10C.

The control signal terminal 130 is connected to the RFIC 4 and the control circuit 10C.

The control circuit 10C is an example of a controller of the APT module 1C and is connected to the FB terminals 151 to 156, the converter circuit 20, and the control signal terminal 130. The control circuit 10C controls the on/off timing of the switches 22 to 25 of the converter circuit 20 to cause the power supply voltage V1 to be output from the converter circuit 20 based on target power supply voltage information for the PA modules 2A and 2B input from the RFIC 4 via the control signal terminal 130 and the FB power supply voltage input via the FB terminals 151 to 156.

The switch 31C is an example of the first switch, is connected between the converter circuit 20 and each of the output terminals 161 to 163 and 167 and performs switching between connection and non-connection between the converter circuit 20 and the output terminals 161 to 163 and 167. The switch 32C is an example of the second switch, is connected between the converter circuit 20 and each of the output terminals 164 to 166 and performs switching between connection and non-connection between the converter circuit 20 and the output terminals 164 to 166. The switch 31C is composed of, for example, four single pole single throw (SPST) switches. The switch 32C is composed of, for example, three SPST switches. At least one SPST switch of the switch 31C and at least one SPST switch of the switch 32C are allowed to conduct simultaneously. In operation, when the PA module 2A and the PA module 2B simultaneously execute transmission of radio frequency sending signals, the at least one SPST switch of the switch 31C and the at least one SPST switch of the switch 32C simultaneously enter into the connection state. The power supply voltage V1 is thereby simultaneously supplied to both of the PA modules 2A and 2B.

With the configuration described above of the APT module 1C, when the PA module 2A and the PA module 2B simultaneously execute transmission of radio frequency sending signals, the same power supply voltage V1 is supplied from the APT module 1C to each of the PA modules 2A and 2B. That is, the APT module 1C does not supply the plurality of different power supply voltages in an exemplary aspect, and thus the circuit configuration is simplified. The small APT module 1C can thus be provided to simultaneously supply the power supply voltage V1 to the power amplifiers 41 to 46.

### [6 Layout of APT Module and Communication Device]

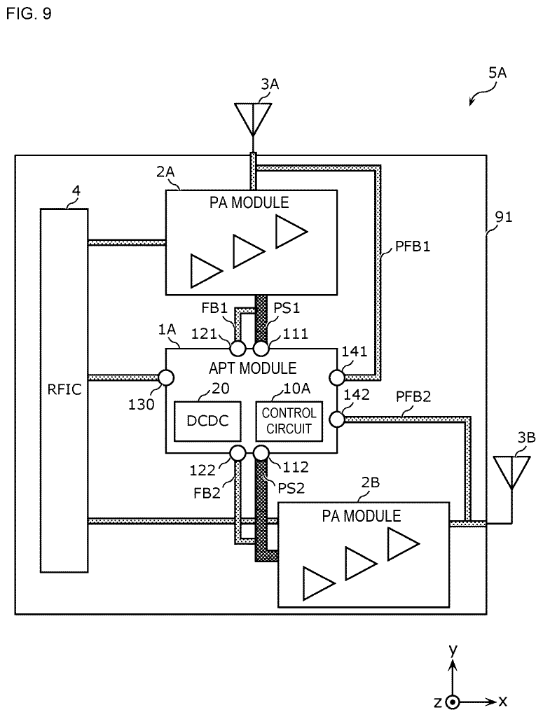

First, the layout of the communication device 5A according to Modification 2 on a mother board 91 will be described with reference to FIG. 9. FIG. 9 is a plan view of the communication device 5A according to Modification 2. As illustrated in the figure, the communication device 5A includes the mother board 91, the RFIC 4, the APT module 1A, and the PA modules 2A and 2B. The PA module 2A is an example of the first amplifying module, and the PA module 2B is an example of the second amplifying module.

As the mother board 91, for example, a printing circuit board, one of a low temperature co-fired ceramics (LTCC) substrate and a high temperature co-fired ceramics (HTCC) substrate that have a layered structure of a plurality of dielectric layers, a component-embedded board, a substrate having a redistribution layer (RDL), and a printing circuit board may be used, but the mother board 91 is not limited to these.

The RFIC 4, the APT module 1A, and the PA modules 2A and 2B are disposed on the main surface of the mother board 91.

In plan view of the main surface of the mother board 91, the APT module 1A is disposed between the PA module 2A and the PA module 2B.

This configuration enables the distance between the APT module 1A and the PA module 2A and the distance between the APT module 1A and the PA module 2B to be shortened. The power supply voltage V1 may thus be supplied from the APT module 1A to both of the PA modules 2A and 2B with low loss.

For example, the power amplifiers 41 to 43 are primary amplifiers, and the power amplifiers 44 to 46 are secondary amplifiers. In other words, the PA module 2A is a primary module, and the PA module 2B is a secondary module. In this case, the length of the wiring line connecting the PA module 2A and the APT module 1A is shorter than the length of the wiring line connecting the PA module 2B and the APT module 1A.

A voltage drop of the power supply voltage V1 to be supplied from the APT module 1A to the PA module 2A may thereby be made lower than a voltage drop of the power supply voltage V1 to be supplied from the APT module 1A to the PA module 2B. The power supply voltage V1 may thus be supplied from the APT module 1A to the primary module with lower loss.

The signal path PS1 serving as the wiring line connecting the output terminal 111 and the PA module 2A may be thicker than a FB wiring line FB1 connecting the FB terminal 121 and the PA module 2A, and the signal path PS2 serving as the wiring line connecting the output terminal 112 and the PA module 2B may be thicker than a FB wiring line FB2 connecting the FB terminal 122 and the PA module 2B.

The voltage drop of the power supply voltage V1 to be supplied from the APT module 1A to the PA module 2A and the voltage drop of the power supply voltage V1 to be supplied from the APT module 1A to the PA module 2B may thereby be made lower.

The length of the wiring line denotes a length in a direction in which current of a conductor electrically connecting two terminals flows. The thickness of the wiring line denotes: (1) a value obtained in such a manner that the cross sections of the wiring line are obtained by cutting the wiring line in a direction orthogonal to the direction in which the current flows and are averaged in the direction in which the current of the wiring line flows; (2) a value obtained in such a manner that the cross sections of the wiring line are obtained by cutting the wiring line in the direction orthogonal to the direction in which the current flows and are sampled at predetermined intervals in the direction in which the current of the wiring line flows and that the sampled values are averaged; and (3) a value obtained in such a manner that the cross sections of the wiring line are obtained by cutting the wiring line in the direction orthogonal to the direction in which the current flows and are sampled at any point in the direction in which the current of the wiring line flows and that the sampled values are averaged.

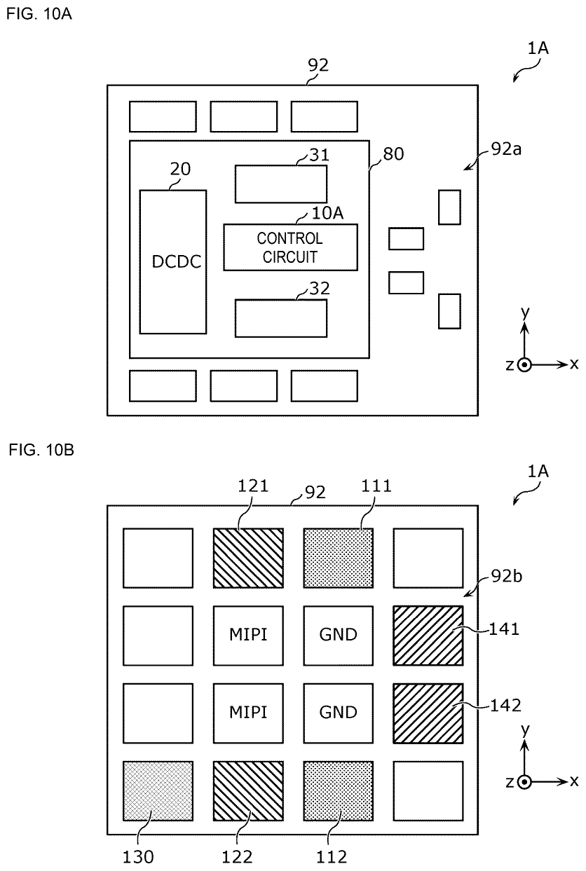

The layout of components on a module laminate 92 of the APT module 1A according to Modification 2 will then be described with reference to FIGS. 10A and 10B. FIG. 10A is a plan view of a main surface 92a of the APT module 1A according to Modification 2 and is a view of the main surface 92a of the module laminate 92 seen from the positive z-axis direction side. FIG. 10B is a plan view of a main surface 92b of the APT module 1A according to Modification 2 and is a view of the main surface 92b side of the module laminate 92 seen through the module laminate 92 from the positive z-axis direction side.

The module laminate 92 has the main surfaces 92a and 92b opposite to each other. As the module laminate 92, for example, any of a LTCC substrate and a HTCC substrate that have a laminated structure of a plurality of dielectric layers, a component-embedded board, a substrate having a RDL, or a printing circuit board may be used, but the module laminate 92 is not limited to these.

In the exemplary aspect, the converter circuit 20 and the control circuit 10A are disposed on the main surface 92a, and the output terminals 111 and 112 and the FB terminals 121 and 122 are disposed on the main surface 92b.

This configuration causes the circuit components and the terminals included in the APT module 1A to be disposed in such a manner as to be divided on both of the main surfaces of the module laminate 92 and thus enables the APT module 1A to be downsized.

The converter circuit 20 and the control circuit 10A may be included in a semiconductor IC 80. The semiconductor IC 80 may be formed by using, for example, a complementary metal oxide semiconductor (CMOS) and specifically, may be manufactured in a silicon on insulator (SOI) process. The semiconductor IC 80 is not limited to the CMOS.

This configuration causes the converter circuit 20 and the control circuit 10A to be integrated and thus enables the APT module 1A to be downsized.

In plan view of the main surface 92b, the output terminal 111 and the FB terminal 121 are adjacent to each other, and the output terminal 112 and the FB terminal 122 are adjacent to each other.

This configuration enables FB wiring lines FB1 and FB2 to be shortened and thus enables the FB voltages V_{FB1} and V_{FB2} to be detected at the FB terminals 121 and 122 with high accuracy.

In plan view of the main surface 92b, a ground terminal is disposed between the output terminal 111 and the output terminal 112.

This configuration enables mutual interference between the power supply voltage output from the output terminal 111 and the power supply voltage output from the output terminal 112 to be reduced.

The module laminate 92 has a rectangle shape, and in plan view of the main surface 92b, the output terminal 111 and the output terminal 112 are disposed adjacent to each other on two sides facing each other of the four sides of the module laminate 92.

This configuration enables the distance between the output terminal 111 and the output terminal 112 to be ensured and thus enables the mutual interference between the power supply voltage output from the output terminal 111 and the power supply voltage output from the output terminal 112 to be reduced.

In plan view of the main surface 92b, control terminals for inputting and outputting digital control signals are disposed between the FB terminal 121 and the FB terminal 122. The control terminals (MIPIs in FIG. 10B) are terminals for supplying, for example, digital control signals using a source synchronization method from the control circuit 10A to the switches 31 and 32.

This configuration enables the mutual interference between the FB voltage V_{FB1} detected at the FB terminal 121 and the FB voltage V_{FB2} detected at the FB terminal 122 to be reduced.

The switches 31 and 32 are disposed on the main surface 92a, and in plan view of the main surface 92a, the control circuit 10A is disposed between the switches 31 and 32.

This configuration enables distance between the switch 31 and the control circuit 10A and the distance between the switch 32 and the control circuit 10A to be shortened. Digital noise attributed to the digital control signals supplied from the control circuit 10A to both of the switches 31 and 32 may thus be prevented from occurring.

### [7 Technical Effects and Others]

As described above, the APT module 1 according to the exemplary embodiment includes the converter circuit 20 that outputs the power supply voltage V1, the output terminals 111 and 112 to which the power supply voltage V1 is applied, the FB terminal 121 connected to the signal path PS1 connecting the output terminal 111 and the power amplifiers 41 to 43, the FB terminal 122 connected to the signal path PS2 connecting the output terminal 112 and the power amplifiers 44 to 46, the control circuit 10 connected to the FB terminals 121 and 122, and the converter circuit 20.

This configuration enables the same power supply voltage V1 to be supplied from the APT module 1 to each of the PA modules 2A and 2B when the PA module 2A and the PA module 2B simultaneously execute transmission of radio frequency sending signals. That is, the APT module 1 does not supply the plurality of different power supply voltages in the exemplary aspect, and thus the circuit configuration is simplified. Accordingly, the small APT module 1 that supplies the power supply voltage to the power amplifiers in simultaneously sending the plurality of radio frequency signals is provided.

For example, the APT module 1 may further include the switch 31 connected between the converter circuit 20 and the output terminal 111 and the switch 32 connected between the converter circuit 20 and the output terminal 112.

This configuration enables an output destination of the power supply voltage V1 to be selected.

For example, in the APT module 1, the switch 31 and the switch 32 may be allowed to conduct simultaneously.

This configuration causes the switches 31 and 32 to conduct simultaneously and thus enables the power supply voltage V1 to be simultaneously applied to both of the output terminals 111 and 112.

For example, in the APT module 1, the control circuit 10 may cause the converter circuit 20 to output, as the power supply voltage V1, higher one of the target voltage V_{TA1} based on the output power of the power amplifiers 41 to 43 and the target voltage V_{TA2} based on the output power of the power amplifiers 44 to 46.

This configuration enables the APT module 1 to supply the power supply voltage V1 appropriate for the power amplifiers 41 to 46 to perform appropriate amplification operations.

For example, in the APT module 1, the control circuit 10 can be configured to increase the power supply voltage V1 when the differential voltage obtained by subtracting the FB voltage V_{FB1} across the FB terminal 121 from the target voltage V_{TA1} is higher than or equal to Vth1, or when the differential voltage obtained by subtracting the FB voltage V_{FB2} across the FB terminal 122 from the target voltage V_{TA2} is higher than or equal to Vth2.

This configuration enables the APT module 1 to supply the power supply voltage V1 for the power amplifiers 41 to 46 to perform appropriate amplification operations according to an amplification state change in the power amplifiers 41 to 46.

For example, the APT module 1 may further include a LUT in advance storing the correlation data indicating the relationship between the power supply voltages to be supplied to the power amplifiers 41 to 46 and the output power of the power amplifiers 41 to 46. The control circuit 10 may estimate the sum of the output power of the power amplifiers 41 to 43 and the output power of the power amplifiers 44 to 46 based on the power supply voltage V1 and the correlation data and control the power supply voltage V1 to prevent the sum from exceeding Pth3.

This configuration enables the APT module 1 to meet restrictions on the power of the radio frequency signal output from the communication device 5 and also to supply the power supply voltage V1 for the power amplifiers 41 to 46 to perform appropriate amplification operations.

For example, in the APT modules 1 and 1A, the control circuits 10 and 10A can be configured to decrease the power supply voltage V1 when the output power of the radio frequency signals output from the power amplifiers 41 to 43 exceeds Pth4, or when the output power of the radio frequency signals output from the power amplifiers 44 to 46 exceeds Pth5.

This configuration causes the signal distortion to be prevented according to the magnitude of the output power of the power amplifiers 41 to 46 and enables, to be supplied, the power supply voltage V1 appropriate for the power amplifiers 41 to 46 to perform appropriate amplification operations.

For example, the APT module 1A may further include the output power FB terminal 141 connected to the signal output ports of the power amplifiers 41 to 43 and the output power FB terminal 142 connected to the signal output ports of the power amplifiers 44 to 46. Thus, the control circuit 10A can be configured to decrease the power supply voltage V1 when the power value detected at the output power FB terminal 141 exceeds Pth4, or when the power value detected at the output power FB terminal 142 exceeds Pth5.

This configuration causes the signal distortion to be prevented according to the magnitude of the output power of the power amplifiers 41 to 46 and thus enables, to be supplied, the power supply voltage V1 appropriate for the power amplifiers 41 to 46 to perform appropriate amplification operations.

For example, the APT module 1A may further include the module laminate 92 having the main surfaces 92a and 92b opposite to each other. The converter circuit 20 and the control circuit 10A may be disposed on the main surface 92a, and the output terminals 111 and 112 and the FB terminals 121 and 122 may be disposed on the main surface 92b.

This configuration causes the circuit components and the terminals included in the APT module 1A to be disposed in such a manner as to be divided on both of the main surfaces of the module laminate 92 and thus enables the APT module 1A to be downsized.

For example, in the APT module 1A, the converter circuit 20 and the control circuit 10A can be included in the semiconductor IC 80.

This configuration causes the converter circuit 20 and the control circuit 10A to be integrated and thus enables the APT module 1A to be downsized.

For example, in the APT module 1A, in plan view of the main surface 92b, the output terminal 111 and the FB terminal 121 may be adjacent to each other, and the output terminal 112 and the FB terminal 122 may be adjacent to each other.

This configuration enables the FB wiring lines FB1 and FB2 to be shortened and thus the FB voltages V_{FB1} and V_{FB2} to be detected at the FB terminals 121 and 122 with high accuracy.

For example, in the APT module 1A, in plan view of the main surface 92b, the control terminal for inputting and outputting the digital control signal may be disposed between the FB terminal 121 and the FB terminal 122.

This configuration enables the mutual interference between the FB voltage V_{FB1} detected at the FB terminal 121 and the FB voltage V_{FB2} detected at the FB terminal 122 to be reduced.

For example, in the APT module 1A, the converter circuit 20, the control circuit 10A, and the switches 31 and 32 may be disposed on the main surface 92a, and in plan view of the main surface 92a, the control circuit 10A may be disposed between the switches 31 and 32.

This configuration enables the distance between the switch 31 and the control circuit 10A and the distance between the switch 32 and the control circuit 10A to be shortened. Digital noise attributed to the digital control signals supplied from the control circuit 10A to both of the switches 31 and 32 may thus be prevented from occurring.

The communication device 5A according to Modification 2 of this embodiment includes the RFIC 4, the APT module 1A that transmits a radio frequency signal between the RFIC 4 and the antennas 3A and 3B, the PA module 2A connected between the APT module 1A and the antenna 3A and including the power amplifiers 41 to 43, the PA module 2B connected between the APT module 1A and the antenna 3B and including the power amplifiers 44 to 46, and the mother board 91 on which the RFIC 4, the APT module 1A, and the PA modules 2A and 2B are disposed. In plan view of the main surface of the mother board 91, the APT module 1A may be disposed between the PA module 2A and the PA module 2B.

This configuration enables the distance between the APT module 1A and the PA module 2A and the distance between the APT module 1A and the PA module 2B to be shortened. The power supply voltage V1 may thus be supplied from the APT module 1A to both of the PA modules 2A and 2B with low loss.

In the communication device 5A, the power amplifiers 41 to 43 may be primary amplifiers, the power amplifiers 44 to 46 may be the secondary amplifiers, and the length of the wiring line connecting the PA module 2A and the APT module 1A may be shorter than the length of the wiring line connecting the PA module 2B and the APT module 1A.

This configuration enables the voltage drop of the power supply voltage V1 to be supplied from the APT module 1A to the PA module 2A to be made lower than the voltage drop of the power supply voltage V1 to be supplied from the APT module 1A to the PA module 2B. The power supply voltage V1 may thus be supplied from the APT module 1A to the primary module with lower loss.

In the communication device 5A, the signal path PS1 connecting the output terminal 111 and the PA module 2A may be thicker than the FB wiring line FB1 connecting the FB terminal 121 and the PA module 2A, and the signal path PS2 connecting the output terminal 112 and the PA module 2B may be thicker than the FB wiring line FB2 connecting the FB terminal 122 and the PA module 2B.

This configuration enables, to be made lower, the voltage drop of the power supply voltage V1 to be supplied from the APT module 1A to the PA module 2A and the voltage drop of the power supply voltage V1 to be supplied from the APT module 1A to the PA module 2B.

The APT circuit according to this exemplary embodiment includes the converter circuit 20 configured to convert the input voltage to the power supply voltage V1, the switch 31 disposed on the first path that connects the converter circuit 20 and the power amplifiers 41 to 43 and through which the power supply voltage V1 is supplied to the power amplifiers 41 to 43, and the switch 32 disposed on the second path that connects the converter circuit 20 and the power amplifiers 44 to 46 and through which the power supply voltage V1 is supplied to the power amplifiers 44 to 46, and the switch 31 and the switch 32 are allowed to conduct simultaneously.

This configuration enables the same power supply voltage V1 to be supplied from the APT circuit to each of the PA modules 2A and 2B when the switches 31 and 32 simultaneously enter into the conduction state. That is, the APT circuit does not supply the plurality of different power supply voltages in an exemplary aspect, and thus the circuit configuration is simplified. The small and simplified APT circuit can thus be provided that is configured to simultaneously supply the power supply voltage V1 to the power amplifiers 41 to 46.

In the power supply voltage supply method according to this embodiment, a higher voltage of the target voltage V_{TA1} based on the output power of the power amplifiers 41 to 43 and the target voltage V_{TA2} based on the output power of the power amplifiers 44 to 46 is selected as the power supply voltage V1, and the selected power supply voltage V1 is supplied to both of the power amplifiers 41 to 43 and the power amplifiers 44 to 46.

This configuration enables, to be supplied, the power supply voltage V1 appropriate for the power amplifiers 41 to 46 to perform appropriate amplification operations.

Further, in the power supply voltage supply method according to this embodiment, the power supply voltage V1 can be increased when the differential voltage obtained by subtracting the differential voltage across the power supply voltage supply lines connected to the power amplifiers 41 to 43 from the target voltage V_{TA1} is higher than or equal to Vth1, or when the differential voltage obtained by subtracting the differential voltage across the power supply voltage supply lines connected to the power amplifiers 44 to 46 from the target voltage V_{TA2} is higher than or equal to Vth2.

This configuration enables, to be supplied, the power supply voltage V1 appropriate for the power amplifiers 41 to 46 to perform appropriate amplification operations according to an amplification state change in the power amplifiers 41 to 46.

Further, in the power supply voltage supply method according to this embodiment, the power supply voltage V1 can be deceased when the output power of the radio frequency signals output from the power amplifiers 41 to 43 exceeds Pth4, or when the output power of the radio frequency signals output from the power amplifiers 44 to 46 exceeds Pth5.

This configuration causes the signal distortion to be prevented according to the magnitude of the output power of the power amplifiers 41 to 46 and enables, to be supplied, the power supply voltage V1 appropriate for the power amplifiers 41 to 46 to perform appropriate amplification operations.

### Additional Exemplary Embodiments

The APT module, the APT circuit, the communication device, and the power supply voltage supply method according to the exemplary aspects of the present disclosure have heretofore been described based on the embodiment and the modifications. However, the APT module, the APT circuit, the communication device, and the power supply voltage supply method are not limited to the embodiment and the modifications described above. Another embodiment implemented by combining any components in the above-described embodiment and modifications, a modification obtained by applying, to any of the embodiment and the modifications conceived of those skilled in the art without departing from the spirit of the present disclosure, and various types of equipment having any of the APT module, the APT circuit, and the communication device that are built therein are also included in the present disclosure.

For example, in the circuit configuration of the APT module, the APT circuit, and the communication device according to the embodiment and the modifications described above, another circuit element, another wiring line, or the like may be inserted into a path connecting a circuit element and a signal path that are disclosed in the drawings.

The features of the amplifier circuits and the communication devices described based on the exemplary embodiment above will hereinafter be described.

<1> An average power tracking module includes: a first output terminal and a second output terminal; a converter circuit configured to output a first voltage to the first output terminal and the second output terminal; a first feedback terminal connected to a path between a first power amplifier and the first output terminal; a second feedback terminal connected to a path between a second power amplifier and the second output terminal; and a control circuit connected to the first feedback terminal, the second feedback terminal, and the converter circuit.

The average power tracking module according to <1> further includes a first switch connected between the converter circuit and the first output terminal; and a second switch connected between the converter circuit and the second output terminal.

<3> In the average power tracking module according to <2>, the first switch and the second switch are configured to conduct simultaneously.

<4> In the average power tracking module according to any one of <1> to <3>, the control circuit is configured to cause a higher one of a first power supply voltage and a second power supply voltage to be output as the first voltage from the converter circuit at a predetermined time, the first power supply voltage being to be supplied at the predetermined time based on output power of the first power amplifier, the second power supply voltage being to be supplied at the predetermined time based on output power of the second power amplifier.

<5> In the average power tracking module according to <4>, the control circuit can be configured to increase the first voltage when a differential voltage obtained by subtracting a voltage across the first feedback terminal from the first power supply voltage is higher than or equal to a first threshold, or a differential voltage obtained by subtracting a voltage across the second feedback terminal from the second power supply voltage is higher than or equal to a second threshold.

<6> The average power tracking module according to <4> further includes: a memory configured to store correlation data indicating a relationship between a power supply voltage to be supplied to the first power amplifier and the output power of the first power amplifier and a relationship between a power supply voltage to be supplied to the second power amplifier and the output power of the second power amplifier. In this aspect, the control circuit can be configured to estimate a sum of the output power of the first power amplifier and the output power of the second power amplifier based on the first voltage and the correlation data and controls the first voltage to prevent the sum from exceeding a third threshold.

<7> In the average power tracking module according to <4>, the control circuit can be configured to decrease the first voltage when output power of a radio frequency signal output from the first power amplifier exceeds a fourth threshold, or output power of a radio frequency signal output from the second power amplifier exceeds a fifth threshold.

<8> The average power tracking module according to <4> further includes: a third feedback terminal connected to a signal output port of the first power amplifier; and a fourth feedback terminal connected to a signal output port of the second power amplifier. In this aspect, the control circuit can be configured to decrease the first voltage when a power value detected at the third feedback terminal exceeds a fourth threshold, or a power value detected at the fourth feedback terminal exceeds a fifth threshold.

<9> The average power tracking module according to any one of <1> to <8> further includes: a module laminate having a first main surface and a second main surface that are opposite to each other. The converter circuit and the control circuit are disposed on the first main surface, and the first output terminal, the second output terminal, the first feedback terminal, and the second feedback terminal are disposed on the second main surface.

<10> In the average power tracking module according to <9>, the converter circuit and the control circuit are included in a semiconductor IC.

<11> In the average power tracking module according to <9> or <10>, in a plan view of the second main surface, the first output terminal and the first feedback terminal are adjacent to each other, and the second output terminal and the second feedback terminal are adjacent to each other.

<12> In the average power tracking module according to any one of <9> to <11>, in a plan view of the second main surface, a control terminal for inputting and outputting a digital control signal is disposed between the first feedback terminal and the second feedback terminal.

<13> The average power tracking module according to <2> further includes: a module laminate having a first main surface and a second main surface that are opposite to each other. The converter circuit, the control circuit, the first switch, and the second switch are disposed on the first main surface, and in plan view of the first main surface, the control circuit is disposed between the first switch and the second switch.

<14> A communication device includes: a signal processing circuit configured to process a radio frequency signal; the average power tracking module according to any one of <1> to <13> that is configured to transmit the radio frequency signal between the signal processing circuit and an antenna; a first amplifying module that is connected between the average power tracking module and the antenna and that includes the first power amplifier; a second amplifying module that is connected between the average power tracking module and the antenna and that includes the second power amplifier; and a mother board on which the signal processing circuit, the average power tracking module, the first amplifying module, and the second amplifying module are disposed. In a plan view of a main surface of the mother board, the average power tracking module is disposed between the first amplifying module and the second amplifying module.

<15> In the communication device according to <14>, the first power amplifier is a primary amplifier, the second power amplifier is a secondary amplifier, and a length of a wiring line connecting the first amplifying module and the average power tracking module is shorter than a length of a wiring line connecting the second amplifying module and the average power tracking module.

<16> In the communication device according to <14> or <15>, a wiring line connecting the first output terminal and the first amplifying module is thicker than a wiring line connecting the first feedback terminal and the first amplifying module, and a wiring line connecting the second output terminal and the second amplifying module is thicker than a wiring line connecting the second feedback terminal and the second amplifying module.

<17> An average power tracking circuit includes: a converter circuit configured to output a first voltage; a first switch disposed on a first path between the converter circuit and a first power amplifier and through which the first voltage is supplied to the first power amplifier; and a second switch disposed on a second path between the converter circuit and a second power amplifier and through which the first voltage is supplied to the second power amplifier. The first switch and the second switch are configured to conduct simultaneously.

<18> A method is provided for supplying a power supply voltage to a first power amplifier and a second power amplifier that are configured to simultaneously send respective radio frequency signals. In this aspect, the method includes selecting, as a first voltage, a higher voltage of a first power supply voltage based on output power of the first power amplifier and a second power supply voltage based on output power of the second power amplifier; and supplying the selected first voltage to both of the first power amplifier and the second power amplifier.

<19> The method for supplying a power supply voltage according to <18> further includes: increasing the first voltage when a differential voltage obtained by subtracting a voltage across a power supply voltage supply line connected to the first power amplifier from the first power supply voltage to be supplied at a predetermined time based on the output power of the first power amplifier is higher than or equal to a first threshold, or a differential voltage obtained by subtracting a voltage across a power supply voltage supply line connected to the second power amplifier to be supplied at the predetermined time based on the output power of the second power amplifier from the second power supply voltage is higher than or equal to a second threshold.

<20> The method for supplying a power supply voltage according to <18> or <19> further includes: decreasing the first voltage when output power of one of the radio frequency signals that is output from the first power amplifier exceeds a fourth threshold, or output power of one of the radio frequency signals that is output from the second power amplifier exceeds a fifth threshold.

The exemplary embodiment of the present disclosure is widely usable, as a power supply circuit or a communication device disposed in a front end unit supporting a multiband, for communication equipment such as a mobile phone.

### REFERENCE SIGNS LIST

1, 1A, 1C, 1D APT module
2A, 2B PA module
3A, 3B antenna
4 RFIC
5, 5A, 5B, 5C, 5D communication device
10, 10A, 10C, 10D control circuit
20, 20D converter circuit
21 inductor
22, 23, 24, 25, 31, 31C, 32, 32C, 61, 62, 203 switch
41, 42, 43, 44, 45, 46 power amplifier
51, 52, 53, 54, 55, 56 filter
80 semiconductor IC
91 mother board
92 module laminate
92a, 92b main surface
111, 112, 161, 162, 163, 164, 165, 166, 167 output terminal
121, 122, 151, 152, 153, 154, 155, 156 FB terminal
130 control signal terminal
141, 142 output power FB terminal
201, 202 voltage supply circuit
FB1, FB2, FB11, FB12, FB13, FB21, FB22, FB23 FB wiring line
PFB1, PFB2, PFB3, PFB4 output power FB wiring line
PS1, PS2 signal path
V1 power supply voltage

What is claimed:

1. An average power tracking module comprising:
a first output terminal and a second output terminal;
a converter circuit configured to output a first voltage to the first output terminal and the second output terminal;
a first feedback terminal connected to a path between a first power amplifier and the first output terminal;
a second feedback terminal connected to a path between a second power amplifier and the second output terminal; and
a control circuit connected to the first feedback terminal, the second feedback terminal, and the converter circuit.

2. The average power tracking module according to claim 1, further comprising:
a first switch connected between the converter circuit and the first output terminal; and
a second switch connected between the converter circuit and the second output terminal.

3. The average power tracking module according to claim 2, wherein the first switch and the second switch are configured to conduct simultaneously.

4. The average power tracking module according to claim 1, wherein the control circuit is configured to cause a higher one of a first power supply voltage and a second power supply voltage to be output as the first voltage from the converter circuit at a predetermined time, the first power supply voltage being supplied at the predetermined time based on output power of the first power amplifier, and the second power supply voltage being supplied at the predetermined time based on output power of the second power amplifier.

5. The average power tracking module according to claim 4, wherein the control circuit is configured to increase the first voltage when:
a differential voltage obtained by subtracting a voltage across the first feedback terminal from the first power supply voltage is higher than or equal to a first threshold, or
a differential voltage obtained by subtracting a voltage across the second feedback terminal from the second power supply voltage is higher than or equal to a second threshold.

6. The average power tracking module according to claim 4, further comprising:
a memory configured to store correlation data indicating a relationship between a power supply voltage to be supplied to the first power amplifier and the output power of the first power amplifier and a relationship between a power supply voltage to be supplied to the second power amplifier and the output power of the second power amplifier,
wherein the control circuit is configured to estimate a sum of the output power of the first power amplifier and the output power of the second power amplifier based on the first voltage and the correlation data and to control the first voltage to prevent the sum from exceeding a third threshold.

7. The average power tracking module according to claim 4, wherein the control circuit is configured to decrease the first voltage when:
output power of a radio frequency signal output from the first power amplifier exceeds a fourth threshold, or
output power of a radio frequency signal output from the second power amplifier exceeds a fifth threshold.

8. The average power tracking module according to claim 4, further comprising:
a third feedback terminal connected to a signal output port of the first power amplifier; and
a fourth feedback terminal connected to a signal output port of the second power amplifier,
wherein the control circuit is configured to decrease the first voltage when a power value detected at the third feedback terminal exceeds a fourth threshold, or a power value detected at the fourth feedback terminal exceeds a fifth threshold.

9. The average power tracking module according to claim 1, further comprising:
a module laminate having a first main surface and a second main surface that oppose each other,
wherein the converter circuit and the control circuit are disposed on the first main surface, and
wherein the first output terminal, the second output terminal, the first feedback terminal, and the second feedback terminal are disposed on the second main surface.

10. The average power tracking module according to claim 9, wherein the converter circuit and the control circuit are included in a semiconductor IC.

11. The average power tracking module according to claim 9, wherein in a plan view of the second main surface:
the first output terminal and the first feedback terminal are adjacent to each other, and
the second output terminal and the second feedback terminal are adjacent to each other.

12. The average power tracking module according to claim 9, wherein, in a plan view of the second main surface, a control terminal configured to input and output a digital control signal is disposed between the first feedback terminal and the second feedback terminal.

13. The average power tracking module according to claim 2, further comprising:
a module laminate having a first main surface and a second main surface that oppose each other,
wherein the converter circuit, the control circuit, the first switch, and the second switch are disposed on the first main surface, and
wherein, in a plan view of the first main surface, the control circuit is disposed between the first switch and the second switch.

14. A communication device comprising:
a signal processing circuit configured to process a radio frequency signal;
the average power tracking module according to claim 1, and that is configured to transmit the radio frequency signal between the signal processing circuit and an antenna;
a first amplifying module between the average power tracking module and the antenna and that includes the first power amplifier;
a second amplifying module between the average power tracking module and the antenna and that includes the second power amplifier; and
a mother board on which the signal processing circuit, the average power tracking module, the first amplifying module, and the second amplifying module are disposed,
wherein, in a plan view of a main surface of the mother board, the average power tracking module is disposed between the first amplifying module and the second amplifying module.

15. The communication device according to claim 14,
wherein the first power amplifier is a primary amplifier,
wherein the second power amplifier is a secondary amplifier, and
wherein a length of a wiring line connecting the first amplifying module and the average power tracking module is shorter than a length of a wiring line connecting the second amplifying module and the average power tracking module.

16. The communication device according to claim 14,
wherein a wiring line connecting the first output terminal and the first amplifying module is thicker than a wiring line connecting the first feedback terminal and the first amplifying module, and
wherein a wiring line connecting the second output terminal and the second amplifying module is thicker than a wiring line connecting the second feedback terminal and the second amplifying module.

17. An average power tracking circuit comprising:
a converter circuit configured to output a first voltage;
a first switch disposed on a first path between the converter circuit and a first power amplifier and configured to supply the first voltage to the first power amplifier; and
a second switch disposed on a second path between the converter circuit and a second power amplifier and configured to supply the first voltage to the second power amplifier,
wherein the first switch and the second switch are configured to conduct simultaneously.

18. A method for supplying a power supply voltage to a first power amplifier and a second power amplifier that are configured to simultaneously send respective radio frequency signals, the method comprising:
selecting, as a first voltage, a higher voltage of a first power supply voltage based on output power of the first power amplifier and a second power supply voltage based on output power of the second power amplifier; and
supplying the selected first voltage to both of the first power amplifier and the second power amplifier.

19. The method for supplying a power supply voltage according to claim 18, further comprising increasing the first voltage when:
a differential voltage obtained by subtracting a voltage across a power supply voltage supply line connected to the first power amplifier from the first power supply voltage to be supplied at a predetermined time based on the output power of the first power amplifier is higher than or equal to a first threshold, or
a differential voltage obtained by subtracting a voltage across a power supply voltage supply line connected to the second power amplifier to be supplied at the predetermined time based on the output power of the second power amplifier from the second power supply voltage is higher than or equal to a second threshold.

20. The method for supplying a power supply voltage according to claim 18, further comprising decreasing the first voltage when:
output power of one of the radio frequency signals that is output from the first power amplifier exceeds a fourth threshold, or
output power of one of the radio frequency signals that is output from the second power amplifier exceeds a fifth threshold.
